(19) United States
(12) Patent Application Publication
(10) Pub. No.: US 2025/0329602 A1
(43) Pub. Date: Oct. 23, 2025

(54) SEMICONDUCTOR DEVICE AND LATTICE-SHAPED FIN

(71) Applicant: Renesas Electronics Corporation, Tokyo (JP)

(72) Inventors: Yota NISHITANI, Tokyo (JP); Taketoshi FUKUSHIMA, Tokyo (JP); Tetsu NEGISHI, Tokyo (JP); Takuya KADOGUCHI, Tokyo (JP); Mikiya CHONABAYASHI, Tokyo (JP); Takamitsu YOSHIHARA, Tokyo (JP)

(21) Appl. No.: 19/065,191

(22) Filed: Feb. 27, 2025

(30) Foreign Application Priority Data
Apr. 17, 2024 (JP) 2024-067070

(51) Int. Cl. H01L 23/367; H01L 23/373

(52) U.S. Cl. CPC H01L 23/3672; H01L 23/3735

(57) ABSTRACT

According to one embodiment, the semiconductor device includes: a semiconductor module including a semiconductor chip having a first surface and a second surface; and a lattice-shaped fin close to the second surface side of the semiconductor chip. The lattice-shaped fin includes a first lattice-shaped body and a second lattice-shaped body, the first lattice-shaped body including a plurality of first bars each having a bar shape extending in a first direction, and being spaced from each other in an arrangement direction, thereby forming a plurality of first trenches between the adjacent first bars, and the second lattice-shaped body including a plurality of second bars each having a bar shape extending in a second direction, and being spaced from each other in the arrangement direction, thereby forming a plurality of second trenches between the adjacent second bars. The first lattice-shaped body and the second lattice-shaped body are stacked in a stack direction.

### CROSS-REFERENCE TO RELATED APPLICATION

The disclosure of Japanese Patent Application No. 2024-067070 filed on Apr. 17, 2024, including the specification, drawings and abstract is incorporated herein by reference in its entirety.

### BACKGROUND

The present disclosure relates to a semiconductor device and a lattice-shaped fin.

There are disclosed techniques listed below.

[Patent Document 1] Japanese Unexamined Patent Application Publication No. 2014-183058

[Patent Document 2] Japanese Unexamined Patent Application Publication No. 2012-146801

[Patent Document 3] Japanese Unexamined Patent Application Publication No. 2015-216409

Each of the Patent Documents 1 to 3 discloses a semiconductor device in which a cooler and a power module are integrated.

### SUMMARY

Power modules each has large heat capacity and high power consumption. Thus, appropriate design for cooling and heat radiating is essential due to higher power density. It has been known that insufficient cooling of the power module affects its life and reliability. A semiconductor device having a structure for more simply and efficiently cooling the power module is to be awaited.

Other objects and novel characteristics will become apparent from the description of the present specification and the drawings.

According to one embodiment, a semiconductor device includes: a semiconductor module including a semiconductor chip having a first surface and a second surface opposite to the first surface; and a lattice-shaped fin close to the second surface side of the semiconductor chip. The lattice-shaped fin includes a first lattice-shaped body and a second lattice-shaped body, the first lattice-shaped body including a plurality of first bars each having a bar shape extending in a first direction within a first plane, and one ends of the plurality of first bars and the other ends of the same opposite to the one ends being spaced from each other in an arrangement direction crossing the first direction within the first plane, thereby forming a plurality of first trenches between the adjacent first bars, and the second lattice-shaped body including a plurality of second bars each having a bar shape extending in a second direction crossing the first direction and the arrangement direction within the first plane, and one ends of the plurality of second bars and the other ends of the same opposite to the one ends being spaced from each other in the arrangement direction, thereby forming a plurality of second trenches between the adjacent second bars. The first lattice-shaped body and the second lattice-shaped body are stacked in a stack direction perpendicular to the first plane.

According to one embodiment, a lattice-shaped fin includes a first lattice-shaped body and a second lattice-shaped body, the first lattice-shaped body including a plurality of first bars each having a bar shape extending in a first direction within a first plane, and one ends of the plurality of first bars and the other ends of the same opposite to the one ends being spaced from each other in an arrangement direction crossing the first direction within the first plane, thereby forming a plurality of first trenches between the adjacent first bars, and the second lattice-shaped body including a plurality of second bars each having a bar shape extending in a second direction crossing the first direction and the arrangement direction within the first plane, and one ends of the plurality of second bars and the other ends of the same opposite to the one ends being spaced from each other in the arrangement direction, thereby forming a plurality of second trenches between the adjacent second bars. The first lattice-shaped body and the second lattice-shaped body are stacked in a stack direction perpendicular to the first plane.

According to the embodiments, it is possible to provide a semiconductor device and a lattice-shaped fin capable of enhancing cooling efficiency.

### BRIEF DESCRIPTIONS OF THE DRAWINGS

FIG. 1 is a cross-sectional view illustrating an example of a configuration of a semiconductor device according to a first reference example.

FIG. 2 is a cross-sectional view illustrating an example of a configuration of a semiconductor device according to a second reference example.

FIG. 3 is a cross-sectional view illustrating an example of a configuration of a semiconductor device according to a third reference example.

FIG. 4 is a cross-sectional view illustrating an example of a configuration of a semiconductor device according to a comparative example.

FIG. 5 is a perspective view illustrating an example of a pin fin in the semiconductor device according to the comparative example.

FIG. 6 is a cross-sectional view illustrating an example of the semiconductor device according to the comparative example, to which a refrigerant jacket is attached.

FIG. 7 is a cross-sectional view illustrating an example semiconductor module and a cooling board in the of a semiconductor device according to the comparative example.

FIG. 8 is a perspective view illustrating an example of the refrigerant jacket in the semiconductor device according to the comparative example.

FIG. 9 is a cross-sectional view illustrating an example of the refrigerant jacket in the semiconductor device according to the comparative example, the cross-sectional view being taken along a line IX-IX of FIG. 8.

FIG. 10 is a cross-sectional view illustrating an example of a flow of the refrigerant between the refrigerant jacket and the cooling board in the semiconductor device according to the comparative example.

FIG. 11 is a cross-sectional view illustrating an example of a configuration of a semiconductor device according to a first embodiment.

FIG. 12 is a perspective view illustrating an example of a lattice-shaped fin in the semiconductor device according to the first embodiment.

FIG. 13 is a plan view illustrating an example of the lattice-shaped fin in the semiconductor device according to the first embodiment.

FIG. 14 is a plan view illustrating an example of a first lattice-shaped body included in the lattice-shaped fin in the semiconductor device according to the first embodiment.

FIG. 15 is a plan view illustrating an example of a second lattice-shaped body included in the lattice-shaped fin in the semiconductor device according to the first embodiment.

FIG. 16 is a cross-sectional view illustrating an example of the semiconductor device according to the first embodiment, to which a refrigerant jacket is attached.

FIG. 17 is a plan view illustrating an example of a lattice-shaped fin in a semiconductor device according to a modification example of the first embodiment.

FIG. 18 is a plan view illustrating an example of a first lattice-shaped body included in the lattice-shaped fin in the semiconductor device according to the modification example of the first embodiment.

FIG. 19 is a plan view illustrating an example of a second lattice-shaped body included in the lattice-shaped fin in the semiconductor device according to the modification example of the first embodiment.

FIG. 20 is a cross-sectional view illustrating an example of the lattice-shaped fin in which a plurality of first lattice-shaped bodies and a plurality of second lattice-shaped bodies are stacked in the semiconductor device according to the first embodiment.

FIG. 21 is a cross-sectional view illustrating an example of the lattice-shaped fin in which a plurality of first lattice-shaped bodies and a plurality of second lattice-shaped bodies are stacked in the semiconductor device according to the first embodiment.

FIG. 22 is a graph illustrating an example of “Tjmax” under change of each width of a first bar and a second bar, each width of a first trench and a second trench, and each number of first lattice-shaped bodies and second lattice-shaped bodies, in the semiconductor device according to the first embodiment, where its horizontal axis indicates the number of first lattice-shaped bodies and second lattice-shaped bodies while its vertical axis indicates the Tjmax.

FIG. 23 is a graph illustrating an example of pressure loss under change of each width of the first bar and the second bar, each width of the first trench and the second trench, and each number of the first lattice-shaped bodies and the second lattice-shaped bodies, in the semiconductor device according to the first embodiment, where its horizontal axis indicates the number of the first lattice-shaped bodies and the second lattice-shaped bodies while its vertical axis indicates the pressure loss.

FIG. 24 is a graph illustrating an example of a passage cross-sectional area under change of each width of the first bar and the second bar, each width of the first trench and the second trench, and each number of the first lattice-shaped bodies and the second lattice-shaped bodies, in the semiconductor device according to the first embodiment, where its horizontal axis indicates the number of the first lattice-shaped bodies and the second lattice-shaped bodies while its vertical axis indicates the passage cross-sectional area.

FIG. 25 is a graph illustrating an example of an in-lattice average flow rate under change of each width of the first bar and the second bar, each width of the first trench and the second trench, and each number of the first lattice-shaped bodies and the second lattice-shaped bodies, in the semiconductor device according to the first embodiment, where its horizontal axis indicates the number of the first lattice-shaped bodies and the second lattice-shaped bodies while its vertical axis indicates the in-lattice average flow rate.

FIG. 26 is a graph illustrating an example of a relationship between the pressure loss and the Tjmax under change of each width of the first bar and the second bar, each width of the first trench and the second trench, and each number of the first lattice-shaped bodies and the second lattice-shaped bodies, in the semiconductor device according to the first embodiment, where its horizontal axis indicates the pressure loss while its vertical axis indicates the Tjmax.

FIG. 27 is a cross-sectional view illustrating an example of a configuration of a semiconductor device according to a second embodiment.

FIG. 28 is a cross-sectional view illustrating an example of the configuration of the semiconductor device according to the second embodiment.

FIG. 29 is a cross-sectional view illustrating an example of the configuration of the semiconductor device according to the second embodiment.

FIG. 30 is a cross-sectional view illustrating an example of the configuration of the semiconductor device according to the second embodiment.

### DETAILED DESCRIPTION

The following description and drawings will be omitted or simplified as needed for clear explanation. Note that the same components are denoted with the same reference symbols in each drawing, and will not be repeatedly explained if unnecessary.

Semiconductor devices according to reference examples will be first explained in chapters <First Reference Example>to <Third Reference Example>, and a semiconductor device according to a comparative example will be then explained in a chapter <Comparative Example>. Then, new issues on the semiconductor devices according to the reference examples and the comparative example, which have found by the present inventors, will be explained in a chapter <New Issues Found by Present Inventors>. Semiconductor devices according to first and second embodiments will be described in chapters <First Embodiment>and <Second Embodiment>while being compared with the comparative example. Thereby, the semiconductor devices according to the first and second embodiments will be more clearly described. Note that the first to third reference examples, the comparative example, and the new issued found by the present inventors fall within the technical scope of embodiments.

### First Reference Example

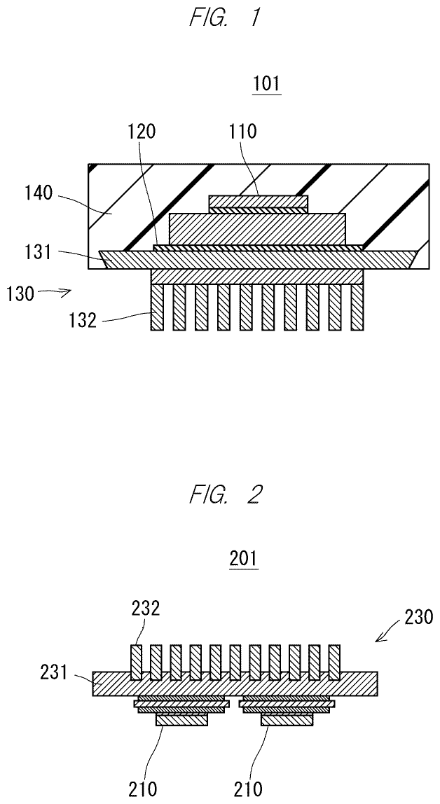

FIG. 1 is a cross-sectional view illustrating an example of a configuration of a semiconductor device 101 according to the first reference example. As illustrated in FIG. 1, the semiconductor device 101 includes a power module 110, an insulating layer 120, a cooler 130, and mold resin 140. The cooler 130 is attached to the power module 110 via the insulating layer 120. The mold resin 140 covers the power module 110, the insulating layer 120, and the cooler 130. The cooler 130 includes a base 131 and a fin 132. The base 131 of the cooler 130 gets narrower as getting farther away (downward in the drawing) from the insulating layer 120. For example, the base 131 has a shape tapered as being farther away from the insulating layer 120 or has a step shape. Thereby, adhesion between the cooler 130 and the mold resin 140 can be enhanced. Therefore, in the semiconductor device 101, peeling between the base 131 and the mold resin 140 at an interface can be suppressed, thereby enhancing cooling performance and reliability.

### Second Reference Example

FIG. 2 is a cross-sectional view illustrating an example of a configuration of a semiconductor device 201 according to the second reference example. As illustrated in FIG. 2, the semiconductor device 201 includes a power module 210 and a cooler 230. The cooler 230 includes a metal member. In the cooler 230, a plurality of concaves are formed by a pressing process, and a fin 232 is brazed in the concaves. The semiconductor device 201 is manufactured at a lower cost than that of a typical process of forming a pin fin shape because of not needing a process such as extrusion molding. In the semiconductor device 201, the fin 232 and a base 231 can be made of different kinds of metals, and the fin 232 can be arranged at any portion, and thus, the degree of freedom of design can be enhanced. Additionally, in the semiconductor device 201, the fin 232 and the base 231 are pressurized and heated by using a brazing material thereby to be tightly bonded (diffusion-bonded or the like).

### Third Reference Example

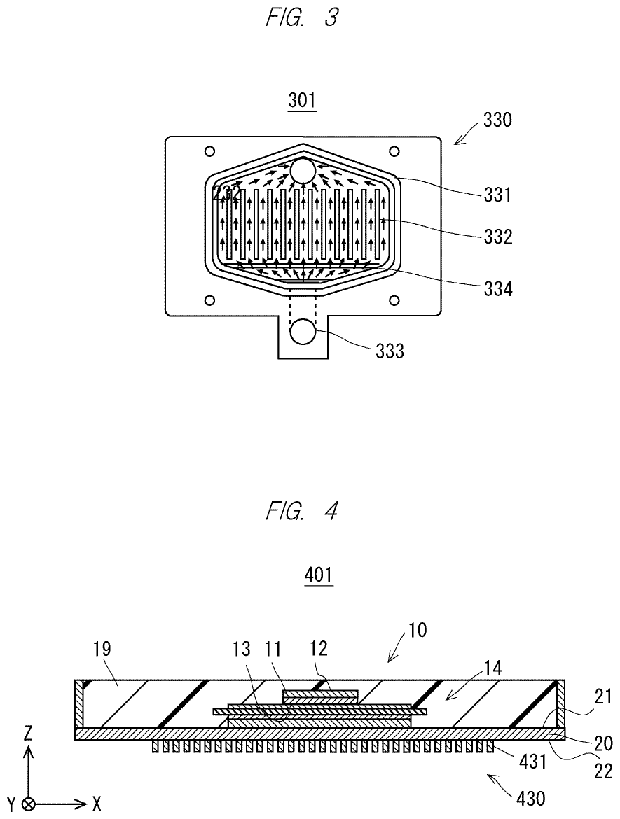

FIG. 3 is a cross-sectional view illustrating an example of a configuration of a semiconductor device 301 according to the third reference example. As illustrated in FIG. 3, the semiconductor device 301 includes a cooler 330. The cooler 330 includes a base 331 with a refrigerant inlet port 333, and a fin 332. A refrigerant 334 flows from the refrigerant inlet port 333 through the base 331 in a folding-fan shape. The fin 332 is formed in the base 331. The fin 332 may be a blade fin made of a plate, a round pin-shaped fin with circular cross section, a polygonal pin-shaped fin, or the like. The refrigerant 334 uniformly flows in the base 331 and thus the semiconductor device 303 can achieve uniform cooling.

### Comparative Example

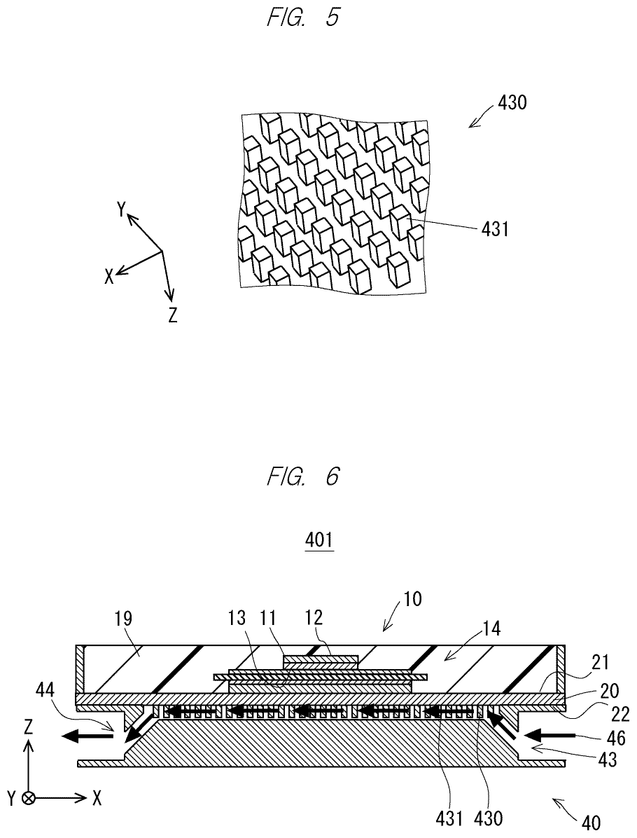

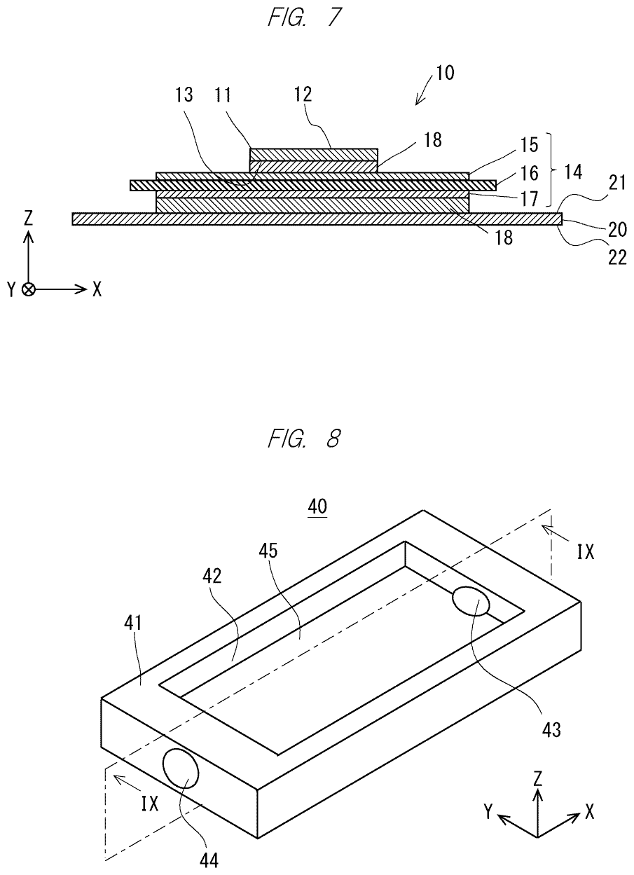

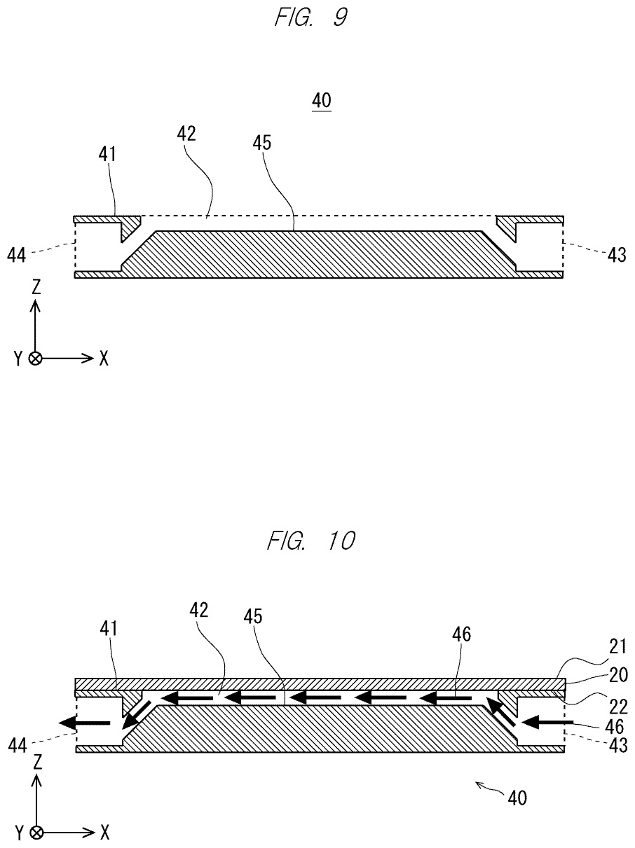

FIG. 4 is a cross-sectional view illustrating an example of a configuration of a semiconductor device 401 according to the comparative example. FIG. 5 is a perspective view illustrating an example of a pin fin 430 in the semiconductor device 401 according to the comparative example. FIG. 6 is a cross-sectional view illustrating an example of the semiconductor device 401 according to the comparative example, to which a refrigerant jacket 40 is attached. FIG. 7 is a cross-sectional view illustrating an example of a semiconductor module 10 and a cooling board 20 in the semiconductor device according to the comparative example. FIG. 8 is a perspective view illustrating an example of the refrigerant jacket 40 in the semiconductor device 401 according to the comparative example. FIG. 9 is a cross-sectional view illustrating an example of the refrigerant jacket 40 in the semiconductor device 401 according to the comparative example, the cross-sectional view being taken along a line IX-IX of FIG. 8. FIG. 10 is a cross-sectional view illustrating an example of a flow of the refrigerant 46 between the refrigerant jacket 40 and the cooling board 20 in the semiconductor device 401 according to the comparative example.

As illustrated in FIGS. 4 to 10, the semiconductor device 401 according to the comparative example includes the semiconductor module 10, the cooling board 20, and the pin fin 430. The cooling board 20 has a heat radiating function, and thus, functions as a heat radiator plate. That is, the heat radiator plate includes the cooling board 20. The semiconductor device 401 may further include the refrigerant jacket 40. An XYZ orthogonal coordinate system is introduced herein for explaining the semiconductor device 401. example, a direction perpendicular to an upper surface 21 of the cooling board 20 is assumed as Z-axis direction, and two directions, which are perpendicular to the Z-axis direction and are perpendicular to each other, are assumed as X-axis direction and Y-axis direction. A positive Z-axis direction may be called upper side, and a negative Z-axis direction may be called lower side. Note that the terms “upper” side and “lower” side are used for explaining the semiconductor device 401 and the like, and do not indicate the directions in which the semiconductor device 401 and the like are actually arranged.

The semiconductor module 10 includes a semiconductor chip 11. The semiconductor chip 11 may be called semiconductor device. The semiconductor chip 11 is, for example, a power semiconductor element. The power semiconductor element may include, for example, a semiconductor for power control such as voltage control or alternating-current/direct-current conversion. Note that the semiconductor chip 11 is not limited to the power semiconductor element. The semiconductor chip 11 may be a semiconductor element including a memory IC or a logic IC. The semiconductor chip 11 may contain silicon (Si), silicon carbide (SiC), or the like as its material. The semiconductor chip 11 has an upper surface 12 and a lower surface 13. The lower surface 13 is opposite to the upper surface 12. The upper surface 12 and the lower surface 13 may be called first surface and second surface, respectively.

The semiconductor module 10 may further include a substrate 14 to which the semiconductor chip 11 is attached, in addition to the semiconductor chip 11. The substrate 14 may include a conductive plate 15, an insulating plate 16, and a heat radiator plate 17. Each of the conductive plate 15, the insulating plate 16, and the heat radiator plate 17 has plate shape. The conductive plate 15 is arranged on a surface of the insulating plate 16 at the positive Z-axis direction side, and the heat radiator plate 17 is arranged on a surface of the insulating plate 16 at the negative Z-axis direction side. In the substrate 14, the conductive plate 15, the insulating plate 16, and the heat radiator plate 17 are stacked in the Z-axis direction. Each of the conductive plate 15 and the heat radiator plate 17 may contain, for example, copper (Cu) or the like as its material. The insulating plate 16 may contain, for example, silicon nitride (SiN) or the like as its material.

The heat radiator plate 17 may be called substrate heat radiator plate. The heat radiator plate 17 may function as a heat radiator plate arranged between the semiconductor chip 11 and the pin fin 430. In this case, the cooling board 20 may not be provided. The pin fin 430 is attached to the lower surface of the heat radiator plate 17.

The semiconductor chip 11 is connected to the positive Z-axis direction side of the conductive plate 15 via a bonding material 18. The cooling board 20 is bonded to the negative Z-axis direction side of the heat radiator plate 17 via a bonding material 18. The bonding material 18 contains, for example, solder. An insulating seal 19 is formed on the upper surface 21 of the cooling board 20 to cover the semiconductor module 10.

The cooling board 20 is arranged between the semiconductor module 10 and the pin fin 430. The cooling board 20 has a plate shape. The pin fin 430 is attached to the lower surface 22 of the cooling board 20.

The pin fin 430 includes a plurality of pins 431. The pins 431 extend downward from the lower surface 22 of the cooling board 20. The pin 431 is arranged to have a predetermined interval from an adjacent pin 431.

An upper surface 41 of the refrigerant jacket 40 has a concave 42. The refrigerant jacket 40 has, for example, a cuboid shape, and its rectangular upper surface 41 has the concave 42. Note that the refrigerant jacket 40 is not limited to have the cuboid shape as far as its upper surface 41 has the concave 42. The upper surface 41 of the refrigerant jacket 40 is bonded to the lower surface 22 of the cooling board 20. In this case, the pin fin 430 is arranged inside the concave 42 of the refrigerant jacket 40.

An inlet port 43 and an outlet port 44, which communicate the concave 42 to the outside, are formed in the refrigerant jacket 40. For example, the inlet port 43 is formed on the positive X-axis direction side of a bottom surface 45 of the concave 42. The outlet port 44 is formed on the negative X-axis direction side of the bottom surface 45 of the concave 42.

A refrigerant 46 flows through the inlet port 43 of the refrigerant jacket 40. The refrigerant 46 is, for example, cooling water. Note that the refrigerant 46 is not limited to the cooling water, and may be coolant gas, organic solvent, or the like. The concave 42 of the refrigerant jacket 40 sealed by the cooling board 20 is filled with the refrigerant 46 flowing through the inlet port 43. The refrigerant 46 passes through a gap between the pins 431 in the concave 42. At this time, the refrigerant 46 exchanges heat with the pins 431. The refrigerant 46 is discharged from the concave 42 of the refrigerant jacket 40 through the outlet port 44.

### New Issues Found by Present Inventors

The cooler 130 and the like for cooling the power module 110 and the like according to the first to third reference examples and the comparative example may have a pin fin shape in order to increase the surface area. The pin fin is typically manufactured by forging. The pin fin has a complicated structure. Thus, a large-scale apparatus is required for manufacturing the pin fin, and it costs much money to manufacture the pin fin. Additionally, since copper has higher heat conductivity than aluminum, copper is appropriate as a material of the cooler 130 and the like, but it has demerits such as high deformation resistance and poor workability. The copper is a factor of making difficulty in the design and the manufacture of the cooler 130 and the like when being used as its material. Thus, in the present disclosure, a semiconductor device including a novel fin-shaped cooler for overcoming the issues is proposed. Thereby, in the semiconductor device according to the present embodiment, its manufacture can be made easy, and the semiconductor chip 11 in the power module or the like can be more efficiently cooled than that in the structures according to the first to third reference examples and the comparative example.

### First Embodiment

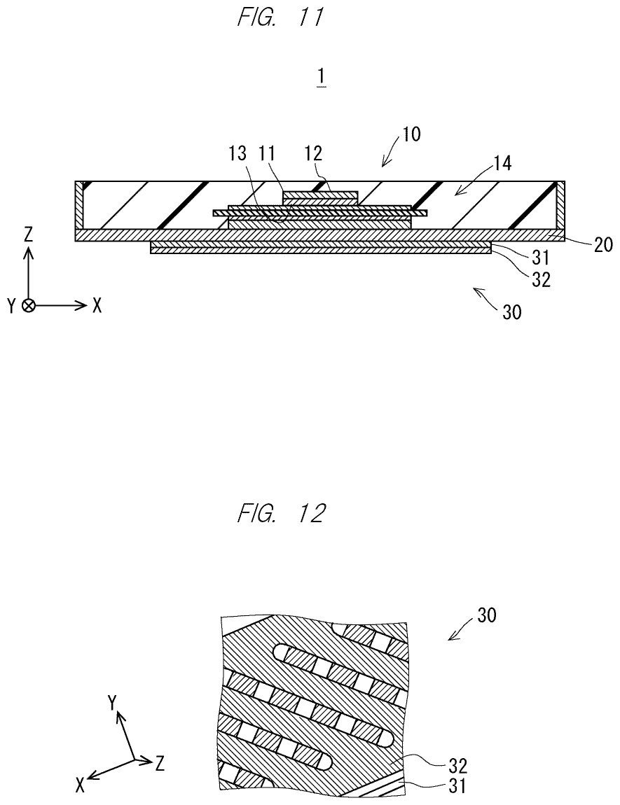

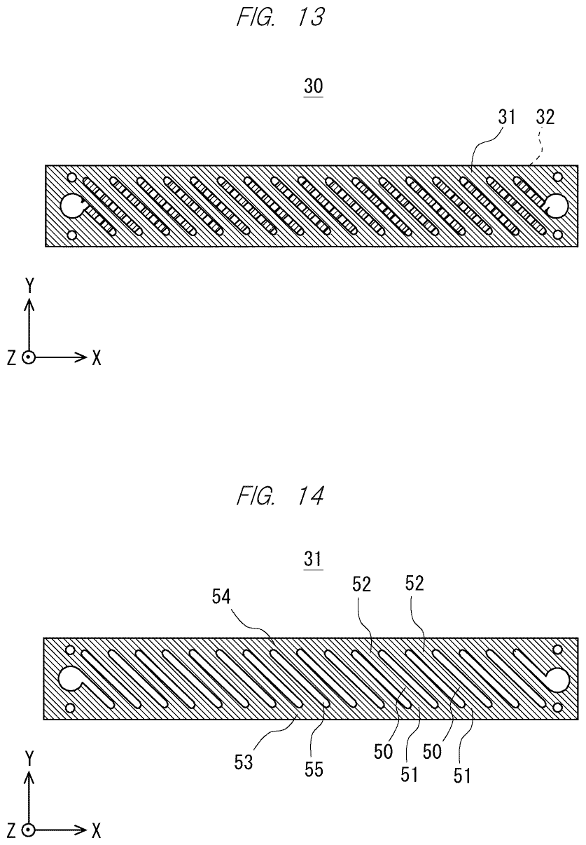

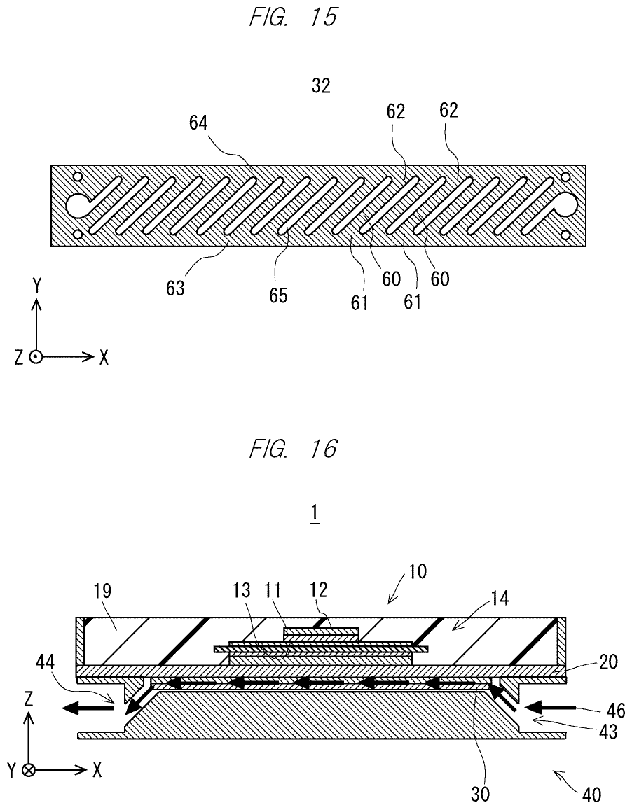

Next, a semiconductor device 1 according to a first embodiment will be describe. FIG. 11 is a cross-sectional view illustrating an example of a configuration of the semiconductor device 1 according to the first embodiment. FIG. 12 is a perspective view illustrating an example of a lattice-shaped fin 30 in the semiconductor device 1 according to the first embodiment. FIG. 13 is a plan view illustrating an example of the lattice-shaped fin 30 in the semiconductor device according to the first embodiment. FIG. 14 is a plan view illustrating an example of a first lattice-shaped body 31 included in the lattice-shaped fin 30 in the semiconductor device according to the first embodiment. FIG. 15 is a plan view illustrating an example of a second lattice-shaped body 32 included in the lattice-shaped fin 30 in the semiconductor device according to the first embodiment. FIG. 16 is a cross-sectional view illustrating an example of the semiconductor device according to the first embodiment, to which the refrigerant jacket 40 is attached.

As illustrated in FIGS. 11 to 16, the semiconductor device 1 includes the semiconductor module 10 and the lattice-shaped fin 30. The semiconductor device 1 may further include the cooling board 20 arranged between the semiconductor module 10 and the lattice-shaped fin 30. The semiconductor device 1 may further include the refrigerant jacket 40.

The lattice-shaped fin 30 is arranged at the lower surface 13 side of the semiconductor chip 11. That is, the lattice-shaped fin 30 is arranged at the negative Z-axis direction side of the semiconductor module 10. For example, the lattice-shaped fin 30 is attached to the lower surface 22 of the cooling board 20.

The semiconductor module 10 includes the semiconductor chip 11 as similar to the comparative example. The semiconductor module 10 may further include the substrate 14 as similar to the comparative example. The substrate 14 is arranged between the semiconductor chip 11 and the lattice-shaped fin 30. The heat radiator plate 17 may function as a heat radiator plate arranged between the semiconductor chip 11 and the lattice-shaped fin 30. In this case, the cooling board 20 may not be provided. The lattice-shaped fin 30 is attached to the lower surface of the heat radiator plate 17.

The lattice-shaped fin 30 may contain at least one of copper and aluminum as its material. The lattice-shaped fin 30 contains such a material with high heat conductivity, thereby enhancing cooling efficiency. Further, the processes can be facilitated.

The lattice-shaped fin 30 includes the first lattice-shaped body 31 and the second lattice-shaped body 32. Each of the first lattice-shaped body 31 and the second lattice-shaped body 32 has a plate shape. Plate surfaces of the first lattice-shaped body 31 and the second lattice-shaped body 32 are oriented in the positive Z-axis direction and in the negative Z-axis direction, respectively. The first lattice-shaped body 31 and the second lattice-shaped body 32 are stacked in the Z-axis direction perpendicular to the XY plane. The Z-axis direction in which the first lattice-shaped body 31 and the second lattice-shaped body 32 are stacked may be called stack direction.

The first lattice-shaped body 31 includes a plurality of first bars 50 each having a bar shape extending in a first direction within the XY plane. The first direction is a direction tilting in the X-axis direction and the Y-axis direction. One ends 51 of the first bars 50 and the other ends 52 of the same opposite to the one ends 51 are spaced from each other in the X-axis direction. The direction in which the one ends 51 and the other ends 52 of the first bars 50 are arranged to be spaced from each other is called arrangement direction. The first bars 50 are arranged as described above, thereby forming a plurality of first trenches 55 between the adjacent first bars 50. The first trenches 55 extend in the first direction. The first trenches 55 penetrate in the Z-axis direction.

The first lattice-shaped body 31 may include a one-end frame 53 and the other-end frame 54. The one-end frame 53 extends in the arrangement direction and is connected to the one ends 51 of the first bars 50. The other-end frame 54 extends in the arrangement direction and is connected to the other ends 52 of the first bars 50. The one-end frame 53 closes one ends of the first trenches 55. The other-end frame 54 closes the other ends of the first trenches 55. The first lattice-shaped body 31 may have a plate shape including the first bars 50, the one-end frame 53, and the other-end frame 54 that are integrally formed. Specifically, the first lattice-shaped body 31 may be formed by punching the first trenches 55 in a rectangular metal plate extending in the X-axis direction.

The second lattice-shaped body 32 includes a plurality of second bars 60 each having a bar shape extending in a second direction within the XY plane. The second direction is a direction tilting in the X-axis direction and the Y-axis direction as well as a direction crossing the first direction and the arrangement direction. One ends 61 of the second bars 60 and the other ends 62 of the same opposite to the one ends 61 are spaced from each other in the X-axis direction that is the arrangement direction. The second bars 60 are arranged as described above, thereby forming a plurality of second trenches 65 between the adjacent second bars 60. The second trenches 65 extend in the second direction. The second trenches 65 penetrate in the Z-axis direction.

The second lattice-shaped body 32 may include a one-end frame 63 and the other-end frame 64. The one-end frame 63 extends in the arrangement direction and is connected to the one ends 61 of the second bars 60. The other-end frame 64 extends in the arrangement direction and is connected to the other ends 62 of the second bars 60. The one-end frame 63 closes one ends of the second trenches 65. The other-end frame 64 closes the other ends of the second trenches 65. The second lattice-shaped body 32 may have a plate shape including the second bars 60, the one-end frame 63, and the other-end frame 64 that are integrally formed. Specifically, the second lattice-shaped body 32 may be formed by punching the second trenches 65 in a rectangular metal plate extending in the X-axis direction.

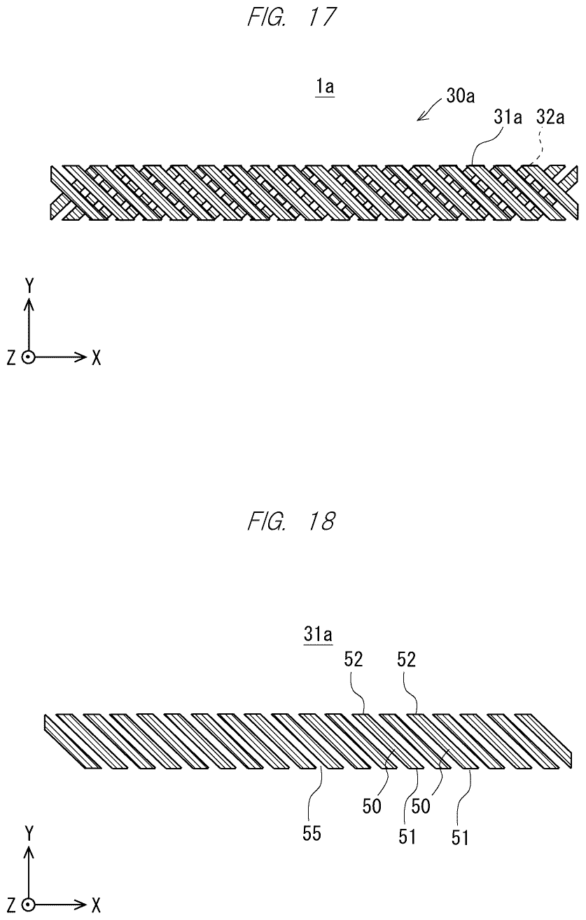

FIG. 17 is a plan view illustrating an example of the lattice-shaped fin 30 in a semiconductor device la according to a modification example of the first embodiment. FIG. 18 is a plan view illustrating an example of a first lattice-shaped body 31a included in the lattice-shaped fin 30a in the semiconductor device la according to the modification example of the first embodiment. FIG. 19 is a plan view illustrating an example of a second lattice-shaped body 32a included in the lattice-shaped fin 30a in the semiconductor device 1a according to the modification example of the first embodiment.

As illustrated in FIGS. 17 to 19, the lattice-shaped fin 30a in the semiconductor device la according to the modification example includes the first lattice-shaped body 31a and the second lattice-shaped body 32a. The first lattice-shaped body 31a does not include the one-end frame 53 and the other-end frame 54. The second lattice-shaped body 32a does not include the one-end frame 63 and the other-end frame 64.

The first lattice-shaped body 31a includes the first bars 50 each having a bar shape extending in the first direction, and the one ends 51 and the other ends 52 of the first bars 50 are spaced from each other in the arrangement direction. The first trenches 55 formed between the adjacent first bars 50 communicate from the end of the first lattice-shaped body 31a at the positive Y-axis direction side to the end thereof at the negative Y-axis direction side. That is, the one ends and the other ends of the first trenches 55 are not closed and are opened.

The second lattice-shaped body 32a includes the second bars 60 each having a bar shape extending in the second direction, and the one ends 61 and the other ends 62 of the second bars 60 are spaced from each other in the arrangement direction. The second trenches 65 formed between the adjacent second bars 60 communicate from the end of the second lattice-shaped body 36a at the positive Y-axis direction side to the end thereof at the negative Y-axis direction side. That is, the one ends and the other ends of the second trenches 65 are not closed and are opened. By the configuration of the lattice-shaped fin 30a as described above, a contact area of the refrigerant 46 can be increased. In the following explanation, the lattice-shaped fin 30 may be replaced with the lattice-shaped fin 30a as needed.

The first lattice-shaped body 31 may have the same shape as the overturned shape of the second lattice-shaped body 32. By the configuration as described above, the manufactured first lattice-shaped body 31 can be functioned as the second lattice-shaped body 32 when being overturned, thereby reducing the manufacturing cost. The number of points of connection between the first trenches 55 and the second trenches 65 may be linearly symmetrical to each other with respect to the Y-axis direction, and thus, the refrigerant 46 can be uniformly flown. Note that the shape of the first lattice-shaped body 31 may be different from the overturned shape of the second lattice-shaped body 32. In this case, the degree of freedom of design can be enhanced.

The lattice-shaped fin 30 may be bonded to the cooling board 20. When the heat radiator plate 17 of the substrate 14 functions as a heat radiator plate, the cooling board 20 may not be provided while the lattice-shaped fin 30 may be bonded to the heat radiator plate 17 of the substrate 14. The lattice-shaped fin 30 may be bonded to the cooling board 20 or the heat radiator plate 17 by metal bonding. Specifically, the lattice-shaped fin 30 may be bonded to the cooling board 20 or the heat radiator plate 17 by a metal containing at least one of solder and sintered silver. The lattice-shaped fin 30 may be directly bonded to the cooling board 20 or the heat radiator plate 17. The lattice-shaped fin 30 may be directly bonded to the cooling board 20 or the heat radiator plate 17 by diffusion bonding.

In the lattice-shaped fin 30, the first trenches 55 communicate with the second trenches 65. The refrigerant jacket 40 has the concave 42 covering the lattice-shaped fin 30. For example, in the semiconductor device 1, the upper surface 41 of the refrigerant jacket 40 is integrally bonded to the lower surface 22 of the cooling board 20. In the semiconductor device 1, the upper surface 41 of the refrigerant jacket 40 may be integrally screwed to the lower surface 22 of the cooling board 20. The thickness of each of the first lattice-shaped body 31 and the second lattice-shaped body 32 in the stack direction is equal to or less than half the depth of the concave 42 of the refrigerant jacket 40 covering the lattice-shaped fin 30. Thereby, the lattice-shaped fin 30 can be housed in the concave 42. The refrigerant 46 flowing in from the inlet port 43 of the refrigerant jacket 40 passes through the first trenches 55 and the second trenches 65 which communicate, and flows out from the outlet port 44.

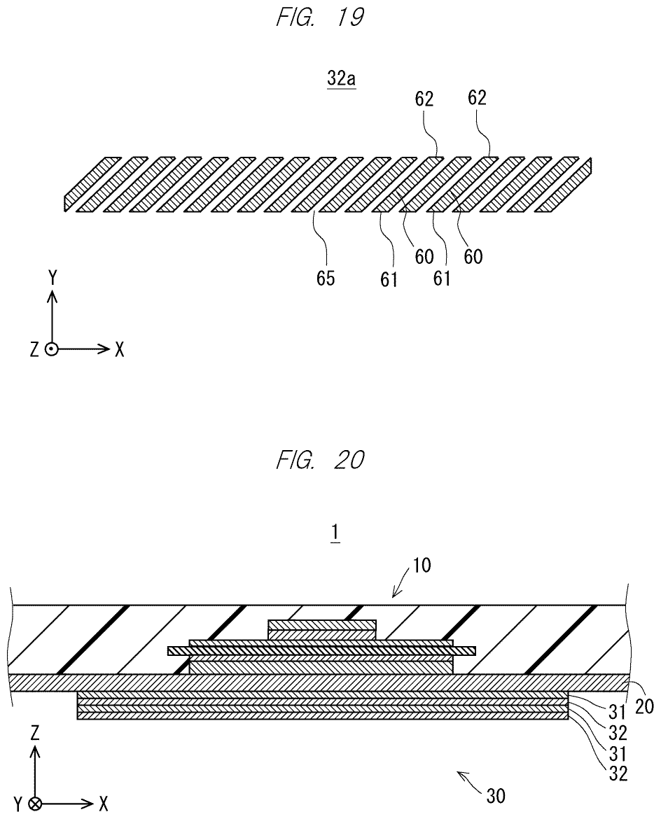

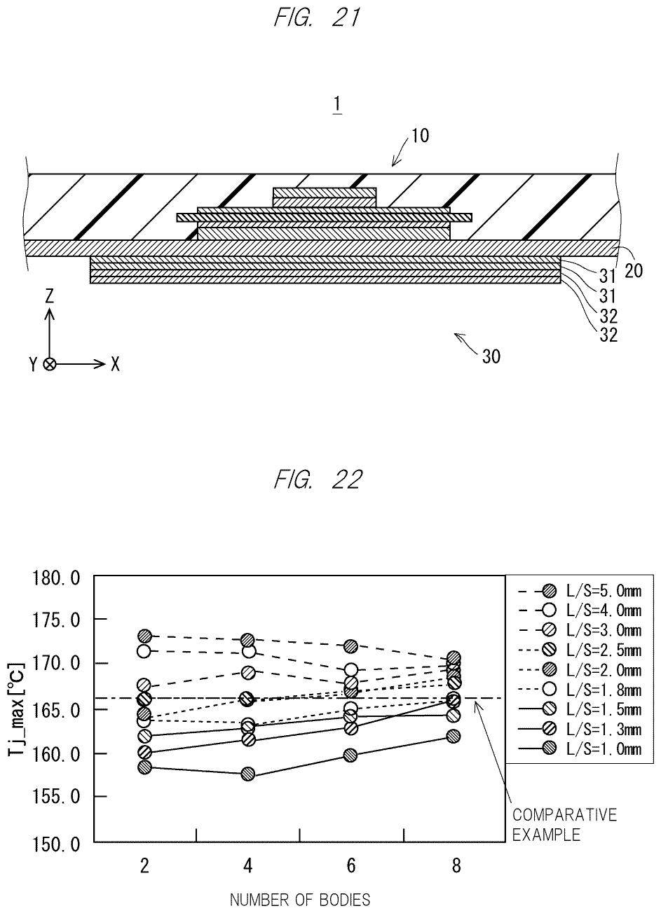

FIGS. 20 and 21 are cross-sectional views each illustrating an example of the lattice-shaped fin 30 in which the first lattice-shaped bodies 31 and the second lattice-shaped bodies 32 are stacked in the semiconductor device 1 according to the first embodiment. As illustrated in FIGS. 20 and 21, in the lattice-shaped fin 30, the first lattice-shaped bodies 31 and the second lattice-shaped bodies 32 are stacked in the stack direction. In FIGS. 20 and 21, although two first lattice-shaped bodies 31 and two second lattice-shaped bodies 32 are stacked, the numbers of them are not limited thereto. Three or more first lattice-shaped bodies 31 and three or more second lattice-shaped bodies 32 may be stacked. Alternatively, the numbers of the first lattice-shaped bodies 31 and the second lattice-shaped bodies 32 may not be the same as each other. As described above, the lattice-shaped fin 30 may include at least the first lattice-shaped bodies 31 stacked in the stack direction or the second lattice-shaped bodies 32 stacked in the stack direction.

As illustrated in FIG. 20, the lattice-shaped fin 30 may include the first lattice-shaped bodies 31 and the second lattice-shaped bodies 32 which are alternately stacked in the stack direction. As illustrated in FIG. 21, in the lattice-shaped fin 30, the first lattice-shaped bodies 31 and the second lattice-shaped bodies 32 may not be alternately stacked in opposite orientations. That is, the lattice-shaped fin 30 may include at least one of a portion where the first lattice-shaped bodies 31 mutually contact and are stacked in the stack direction and a portion where the second lattice-shaped bodies 32 mutually contact and are stacked in the stack direction. As described above, the same first lattice-shaped bodies 31 and second lattice-shaped bodies 32 are stacked, thereby enhancing easiness of manufacture and reducing the cost. Specifically, a metal plate made of, for example, copper or the like with a thickness of 1 mm or more is difficult to be punched in the manufacture. Even if it can be punched, additional cost for burring or the like is required. Thus, the first lattice-shaped bodies 31 and the second lattice-shaped bodies 32 which are thin enough to be easily punched are stacked in the same orientation at desired thickness, thereby eliminating the requirement of the burring and reducing the cost.

The cross section of the first bar 50 of the lattice-shaped fin 30 perpendicular to the first direction and the cross section of the second bar 60 of thereof perpendicular to the second direction may be rectangular. Thereby, the shapes of the passages through which the first trenches 55 and the second trenches 65 communicate can be uniformed, thereby enhancing the flow of the refrigerant 46.

FIG. 22 is a graph illustrating an example of the maximum junction temperature “Tjmax” of the semiconductor chip under change of each width “L” of the first bar 50 and the second bar 60, each width “S” of the first trench 55 and the second trench 65, and each number of the first lattice-shaped bodies 31 and the second lattice-shaped bodies 32, in the semiconductor device 1 according to the first embodiment, where its horizontal axis indicates the number of the first lattice-shaped bodies 31 and the second lattice-shaped bodies 32 while its vertical axis indicates the Tjmax. FIG. 22 also illustrates the Tjmax of the pin fin 430 according to the comparative example.

As illustrated in FIG. 22, Tjmax can be lowered by decreasing the width L and the width S. However, the pressure loss increases since the passage is more complicated. Note that the width L is the width of the first bar 50 perpendicular to the first direction and the stack direction, and the width of the second bar 60 perpendicular to the second direction and the stack direction. The width S is the width of the first trench 55 perpendicular to the first direction and the stack direction, and the width of the second trench 65 perpendicular to the second direction and the stack direction.

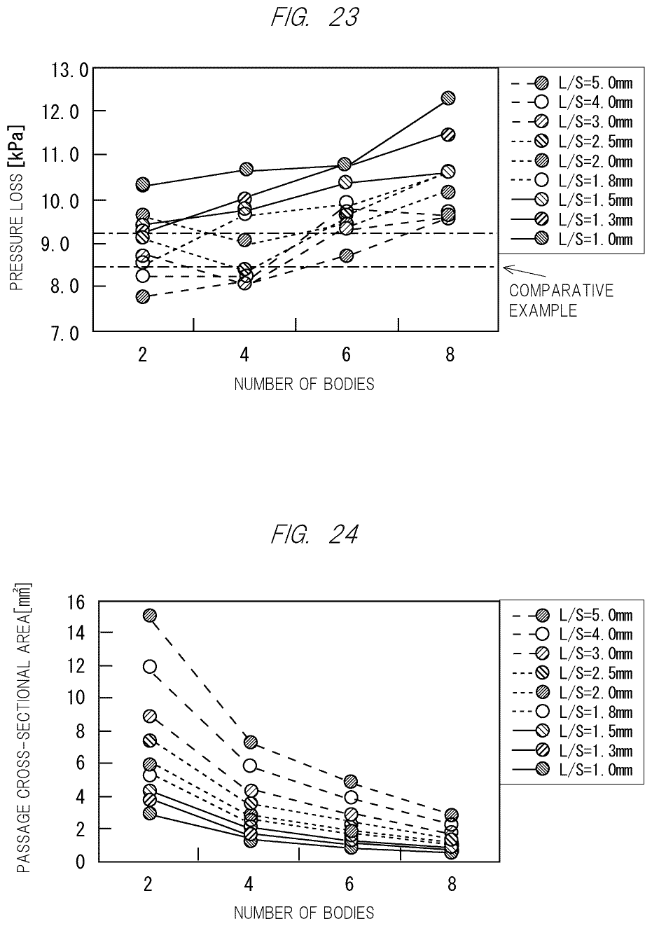

FIG. 23 is a graph illustrating an example of the pressure loss under change of each width L of the first bar 50 and the second bar 60, each width S of the first trench 55 and the second trench 65, and each number of the first lattice-shaped bodies 31 and the second lattice-shaped bodies 32, in the semiconductor device according to the first embodiment, where its horizontal axis indicates the number of the first lattice-shaped bodies 31 and the second lattice-shaped bodies 32 while its vertical axis indicates the pressure loss. FIG. 23 also illustrates the pressure loss of the pin fin 430 according to the comparative example.

As illustrated in FIG. 23, at the width L and width S of 2.0 mm to 3.0 mm, the pressure loss is minimized in a case of four lattice-shaped bodies. It is inferred that this is because the ease of flow exchanges between the thickness direction and the horizontal direction of the lattice-shaped fin 30.

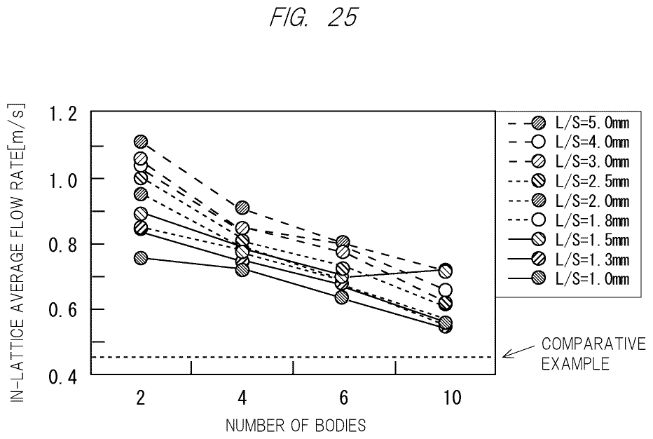

FIG. 24 is a graph illustrating an example of a passage cross-sectional area under change of each width L of the first bar 50 and the second bar 60, each width S of the first trench 55 and the second trench 65, and each number of the first lattice-shaped bodies 31 and the second lattice-shaped bodies 32, in the semiconductor device according to the first embodiment, where its horizontal axis indicates the number of the first lattice-shaped bodies 31 and the second lattice-shaped bodies 32 while its vertical axis indicates the passage cross-sectional area.

FIG. 25 is a graph illustrating an example of an in-lattice average flow rate under change of each width L of the first bar 50 and the second bar 60, each width S of the first trench 55 and the second trench 65, and each number of the first lattice-shaped bodies 31 and the second lattice-shaped bodies 32, in the semiconductor device according to the first embodiment, where its horizontal axis indicates the number of the first lattice-shaped bodies 31 and the second lattice-shaped bodies 32 while its vertical axis indicates the in-lattice average flow rate. FIG. 25 also illustrates the average flow rate of the pin fin 430 according to the comparative example.

As illustrated in FIGS. 24 and 25, the in-lattice average flow rate via the lattice-shaped fin 30 according to the present embodiment is higher than the average flow rate via the pin fin 430 according to the comparative example. In terms of convection heat transfer, it is thought that heat conductivity depends on the flow rate. Therefore, the higher the flow rate is, the higher the heat conductivity is. The average flow rate in the lattice-shaped fin 30 is higher than the average flow rate via the pin fin 430, and thus, the cooling efficiency can be enhanced. The larger the number of the lattice-shaped bodies is, the smaller the passage cross-section area is, thereby more complicating the passage. Thereby, the in-lattice average flow rate decreases.

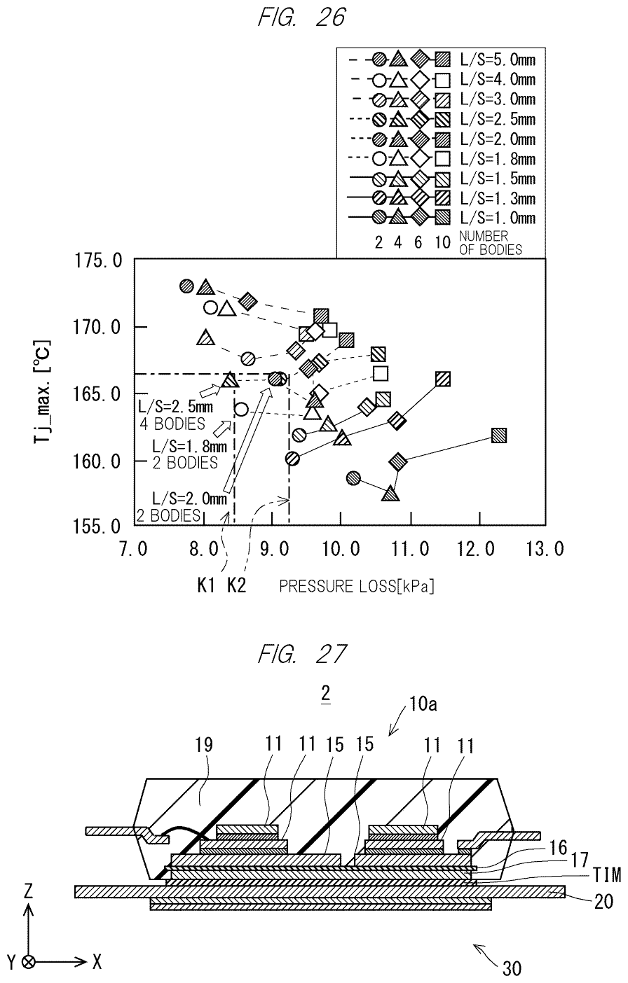

FIG. 26 is a graph illustrating an example of a relationship between the pressure loss and the Tjmax under change of each width L of the first bar 50 and the second bar 60, each width S of the first trench 55 and the second trench 65, and each number of the first lattice-shaped bodies 31 and the second lattice-shaped bodies 32, in the semiconductor device according to the first embodiment, where its horizontal axis indicates the pressure loss while its vertical axis indicates the Tjmax. FIG. 26 also illustrates a relationship “K1” between the pressure loss and the Tjmax in the pin fin 430 according to the comparative example, and a relationship “K2” between the pressure loss and the Tjmax obtained when the pressure loss in the pin fin 430 according to the comparative example is allowed up to +10%.

As illustrated in FIG. 26, preferable values are demonstrated at the width L and width S of 2.5 mm (in a case of four lattice-shaped bodies). Preferable values are demonstrated also at the width L and width S of 1.8 mm (in a case of two lattice-shaped bodies) and at the width L and width S of 2.0 mm (in a case of two lattice-shaped bodies). In consideration of the results of the pressure loss, the width L and the width S are preferably 1.5 mm to 3.0 mm, and more preferably 1.8 mm to 2.5 mm.

Next, effects of the present embodiment will be described. The semiconductor device 1 according to the present embodiment includes the lattice-shaped fin 30. The surface area of the lattice-shaped fin 30 can be easier to increase than that of the pin fin 430 according to the comparative example. Thereby, in the semiconductor device 1, the cooling efficiency can be enhanced.

In terms of convection heat transfer, the heat conductivity depends on the flow rate of the refrigerant 46. Therefore, the higher the flow rate of the refrigerant 46 is, the higher the heat conductivity is. The average flow rate of the refrigerant 46 in the lattice-shaped fin 30 according to the present embodiment is higher than the average flow rate of the refrigerant 46 in the pin fin 430 according to the comparative example, and thus, the cooling efficiency can be enhanced.

The semiconductor device 1 can be easier to be designed than the pin fin 430 according to the comparative example, and thus, can be efficiently cooled at lower cost. Each number of stackings of the first lattice-shaped bodies 31 and the second lattice-shaped bodies 32 and each slit width of the first trench 55 and the second trench 65 or the like can be easily designed, thereby achieving the three-dimensional passage in the thickness direction and in the horizontal direction. Thereby, the pressure loss of the refrigerant 46 can be decreased, and this can contribute to longer life and higher reliability of the semiconductor module 10 including the semiconductor chip 11.

The thickness of each of the first lattice-shaped body 31 and the second lattice-shaped body 32 in the stack direction is equal to or less than half the depth of the concave 42 of the refrigerant jacket 40. Thereby, two or more first lattice-shaped bodies 31 or second lattice-shaped bodies 32 can be stacked in the concave 42. Thus, the passage for the refrigerant 46 can be formed such that the first trenches 55 in the first lattice-shaped body 31 and the second trenches 65 in the second lattice-shaped body 32 communicate.

In the lattice-shaped fin 30, the first lattice-shaped bodies 31 and the second lattice-shaped bodies 32 may not be alternately stacked in opposite orientations. The same first lattice-shaped bodies 31 and second lattice-shaped bodies 32 are stacked, thereby enhancing ease of manufacture, and reducing the cost.

### Second Embodiment

Next, semiconductor devices according to a second embodiment will be described. The semiconductor device according to the present embodiment are different from that according to the first embodiment in that a configuration is sealed by the insulating seal 19. FIGS. 27 to 30 are cross-sectional views illustrating examples of configurations of semiconductor devices 2 to 5 according to the second embodiment.

As illustrated in FIG. 27, the semiconductor device 2 includes a mold including the insulating seal 19, an insulating sheet TIM, the cooling board 20, and the lattice-shaped fin 30. Specifically, in the semiconductor device 2, a semiconductor module 10a is included inside the insulating seal 19. The insulating seal 19 is arranged over the upper surface 21 of the cooling board 20 via the insulating sheet TIM. The insulating sheet TIM is, for example, a resin sheet. The semiconductor module 10a includes a plurality of semiconductor chips 11, a plurality of conductive plates 15, the insulating plate 16, and the heat radiator plate 17. The insulating plate 16 is arranged on the heat radiator plate 17. The two conductive plates 15 are arranged side by side in the X-axis direction, on the insulating Two semiconductor chips 11 are stacked on one plate 16. conductive plate 15, and two semiconductor chips 11 are stacked on the other conductive plate 15.

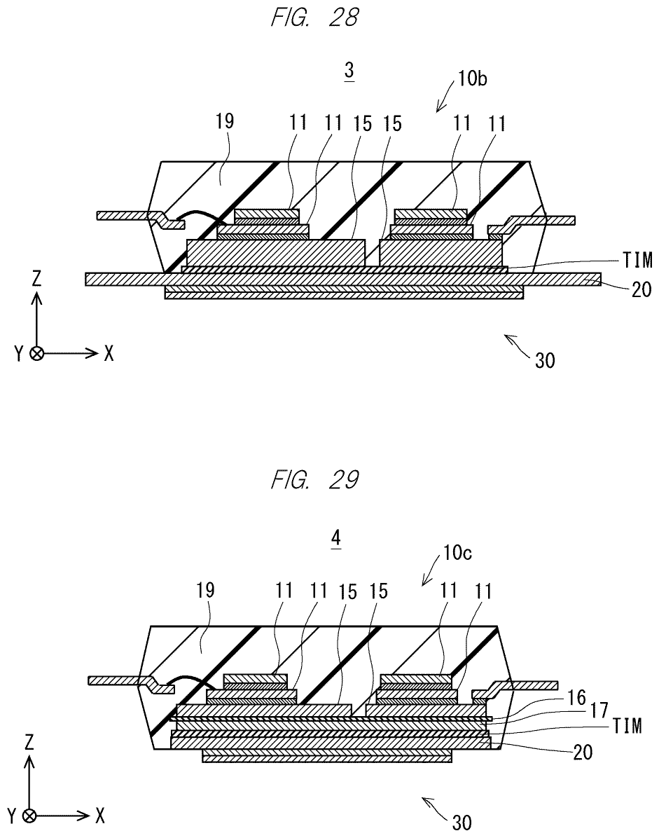

As illustrated in FIG. 28, the semiconductor device 3 includes the mold including the insulating seal 19, the cooling board 20, and the lattice-shaped fin 30. Specifically, in the semiconductor device 3, a semiconductor module 10b is included inside the insulating seal 19. The insulating seal 19 is arranged on the upper surface 21 of the cooling board 20. The semiconductor module 10b includes a plurality of semiconductor chips 11, a plurality of conductive plates 15, and the insulating sheet TIM. Two conductive plates 15 are arranged side by side in the X-axis direction, on the insulating sheet TIM. The conductive plate 15 may contain copper as its material. Two semiconductor chips 11 are stacked on one conductive plate 15, and two semiconductor chips 11 are stacked on the other conductive plate 15.

As illustrated in FIG. 29, in the semiconductor device 4, the insulating sheet TIM and the cooling board 20 are integrated by the mold including the insulating seal 19. Specifically, in the semiconductor device 4, a semiconductor module 10c, the insulating sheet TIM, and the cooling board 20 are included inside the insulating seal 19. The insulating sheet TIM is arranged on the cooling board 20. The semiconductor module 10c is arranged on the insulating sheet TIM. The semiconductor module 10c includes a plurality of semiconductor chips 11, a plurality of conductive plates 15, the insulating plate 16, and the heat radiator plate 17. The insulating plate 16 is arranged on the heat radiator plate 17. Two conductive plates 15 are arranged side by side in the X-axis direction, on the insulating plate 16. Two semiconductor chips 11 are stacked on one conductive plate 15, and two semiconductor chips 11 are stacked on the other conductive plate 15.

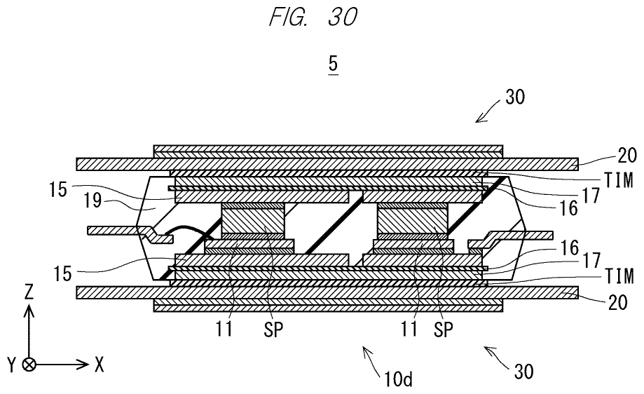

As illustrated in FIG. 30, the semiconductor device 5 includes the mold including the insulating seal 19, insulating sheets TIM provided on up and down sides of the mold, cooling boards 20, and the lattice-shaped fins 30. Specifically, in the semiconductor device 5, a semiconductor module 10d is included inside the insulating seal 19. The insulating sheet TIM, the cooling board 20, and the lattice-shaped fin 30 are arranged at the positive Z-axis direction side of the insulating seal 19 in an order toward the positive Z-axis direction side. The insulating sheet TIM, the cooling board 20, and the lattice-shaped fin 30 are arranged at the negative Z-axis direction side of the insulating seal 19 in an order toward the negative Z-axis direction side.

The heat radiator plate 17, the insulating plate 16, and two conductive plates 15 are arranged at the positive Z-axis direction side of the lower insulating sheet TIM in an order toward the positive Z-axis direction side. Two conductive plates 15 are arranged side by side in the X-axis direction, above the insulating plate 16. The semiconductor chip 11 is stacked on one conductive plate 15, and the semiconductor chip 11 is stacked on the other conductive plate 15.

To the contrary, the heat radiator plate 17, the insulating plate 16, and two conductive plates 15 are arranged at the negative Z-axis direction side of the upper insulating sheet TIM in an order toward the negative Z-axis direction side. Two conductive plates 15 are arranged side by side downward in the X-axis direction, below the insulating plate 16. One conductive plate 15 is bonded to a semiconductor chip 11 via a spacer SP, and the other conductive plate 15 is bonded to a semiconductor chip 11 via a spacer SP.

According to the second embodiment, the components configuring the semiconductor devices 2 to 5 may be variously arranged. Therefore, the degree of freedom of design can be increased. Other configurations and effects of the second embodiment have been described in the first embodiment.

In the foregoing, the present disclosure made by the present inventors has been concretely described based on the embodiments. However, it is needless to say that the present disclosure is not limited to the embodiments, the reference examples, and the comparative example, and various modifications can be made within the scope of the present invention. For example, appropriate combinations the configurations of according to the first to third reference examples, the comparative example, and the first and second embodiments are also within the technical scope of embodiments. The following configurations are also within the technical scope of embodiments.

### Appendix A1

A semiconductor device includes: a semiconductor module including a semiconductor chip having a first surface and a second surface opposite to the first surface; and a lattice-shaped fin close to the second surface side of the semiconductor The lattice-shaped fin includes a first lattice-shaped chip. body and a second lattice-shaped body, the first lattice-shaped body including a plurality of first bars each having a bar shape extending in a first direction within a first plane, and one ends of the plurality of first bars and the other ends of the same opposite to the one ends being spaced from each other in an arrangement direction crossing the first direction within the first plane, thereby forming a plurality of first trenches between the adjacent first bars, and the second lattice-shaped body including a plurality of second bars each having a bar shape extending in a second direction crossing the first direction and the arrangement direction within the first plane, and one ends of the plurality of second bars and the other ends of the same opposite to the one ends being spaced from each other in the arrangement direction, thereby forming a plurality of second trenches between the adjacent second bars. The first lattice-shaped body and the second lattice-shaped body are stacked in a stack direction perpendicular to the first plane.

### Appendix A2

In the semiconductor device according to appendix A1, the lattice-shaped fin is directly bonded to the heat radiator plate.

### Appendix A3

In the semiconductor device according to appendix A2, the lattice-shaped fin is directly bonded to the heat radiator plate by diffusion bonding.

### Appendix B1

A lattice-shaped fin includes a first lattice-shaped body and a second lattice-shaped body, the first lattice-shaped body including a plurality of first bars each having a bar shape extending in a first direction within a first plane, and one ends of the plurality of first bars and the other ends of the same opposite to the one ends being spaced from each other in an arrangement direction crossing the first direction within the first plane, thereby forming a plurality of 1 trenches between the adjacent first bars, and the second lattice-shaped body including a plurality of second bars each having a bar shape extending in a second direction crossing the first direction and the arrangement direction within the first plane, and one ends of the plurality of second bars and the other ends of the same opposite to the one ends being spaced from each other in the arrangement direction, thereby forming a plurality of second trenches between the adjacent second bars. The first lattice-shaped body and the second lattice-shaped body are stacked in a stack direction perpendicular to the first plane.

### Appendix B2

The lattice-shaped fin according to appendix B1, further includes: a heat radiator plate to which the lattice-shaped fin is bonded; and a refrigerant jacket having a concave covering the lattice-shaped fin and being bonded to the heat radiator plate.

What is claimed is:

1. A semiconductor device comprising:
a semiconductor module including a semiconductor chip having a first surface and a second surface opposite to the first surface; and
a lattice-shaped fin close to the second surface side of the semiconductor chip,
wherein the lattice-shaped fin includes:
a first lattice-shaped body including a plurality of first bars each having a bar shape extending in a first direction within a first plane, and one ends of the plurality of first bars and the other ends of the plurality of first bars opposite to the one ends being spaced from each other in an arrangement direction crossing the first direction within the first plane, thereby forming a plurality of first trenches between the adjacent first bars; and
a second lattice-shaped body including a plurality of second bars each having a bar shape extending in a second direction crossing the first direction and the arrangement direction within the first plane, and one ends of the plurality of second bars and the other ends of the plurality of second bars opposite to the one ends being spaced from each other in the arrangement direction, thereby forming a plurality of second trenches between the adjacent second bars, and
the first lattice-shaped body and the second lattice-shaped body are stacked in a stack direction perpendicular to the first plane.

2. The semiconductor device according to claim 1, further comprising:
a heat radiator plate including a cooling board arranged between the semiconductor module and the lattice-shaped fin.

3. The semiconductor device according to claim 1,
wherein the semiconductor module further includes a substrate to which the semiconductor chip is bonded, and
the substrate is arranged between the semiconductor chip and the lattice-shaped fin.

4. The semiconductor device according to claim 3,
wherein the substrate includes:
a conductive plate;
an insulating plate; and
a substrate heat radiator plate.

5. The semiconductor device according to claim 4,
wherein the substrate heat radiator plate functions as a heat radiator plate arranged between the semiconductor chip and the lattice-shaped fin.

6. The semiconductor device according to claim 1, further comprising
a refrigerant jacket having a concave covering the lattice-shaped fin.

7. The semiconductor device according to claim 1,
wherein the first trench and the second trench communicate.

8. The semiconductor device according to claim 1,
wherein the first lattice-shaped body has an integrally-formed plate shape including: the plurality of first bars, a one-end frame being connected to the one ends of the plurality of first bars and extending in the arrangement direction; the other-end frame being connected to the other ends of the plurality of first bars and extending in the arrangement direction,
the second lattice-shaped body has an integrally-formed plate shape including: the plurality of second bars, a one-end frame being connected to the one ends of the plurality of second bars and extending in the arrangement direction; the other-end frame being connected to the other ends of the plurality of second bars and extending in the arrangement direction.

9. The semiconductor device according to claim 1,
wherein the lattice-shaped fin includes at least one of a plurality of the first lattice-shaped bodies stacked in the stack direction and a plurality of the second lattice-shaped bodies stacked in the stack direction.

10. The semiconductor device according to claim 1,
wherein the lattice-shaped fin includes the first lattice-shaped body and the second lattice-shaped body being alternately stacked in the stack direction.

11. The semiconductor device according to claim 1,
wherein the lattice-shaped fin includes at least one of a portion where a plurality of the first lattice-shaped bodies are mutually in contact and stacked in the stack direction and a portion where a plurality of the second lattice-shaped bodies are mutually in contact and stacked in the stack direction.

12. The semiconductor device according to claim 1,
wherein each thickness of the first lattice-shaped body and the second lattice-shaped body in the stack direction is equal to or less than half a depth of a concave of a refrigerant jacket, the concave covering the lattice-shaped fin.

13. The semiconductor device according to claim 1,
wherein the lattice-shaped fin contains at least one of copper and aluminum.

14. The semiconductor device according to claim 2,
wherein the lattice-shaped fin is bonded to the heat radiator plate by metal bonding.

15. The semiconductor device according to claim 1,
wherein the first lattice-shaped body has the same shape as an overturned shape of the second lattice-shaped body.

16. The semiconductor device according to claim 1,
wherein the first lattice-shaped body has a different shape from an overturned shape of the second lattice-shaped body.

17. The semiconductor device according to claim 1,
wherein a cross section of the first bar perpendicular to the first direction and a cross section of the second bar perpendicular to the second direction are rectangular.

18. The semiconductor device according to claim 1,
wherein each of a width of the first bar perpendicular to the first direction and the stack direction and a width of the second bar perpendicular to the second direction and the stack direction is 1.5 mm to 3.0 mm.

19. The semiconductor device according to claim 1,
wherein each of a width of the first trench perpendicular to the first direction and the stack direction and a width of the second trench perpendicular to the second direction and the stack direction is 1.5 mm to 3.0 mm.

20. A lattice-shaped fin comprising:
a first lattice-shaped body including a plurality of first bars each having a bar shape extending in a first direction within a first plane, and one ends of the plurality of first bars and the other ends of the plurality of first bars opposite to the one ends being spaced from each other in an arrangement direction crossing the first direction within the first plane, thereby forming a plurality of first trenches between the adjacent first bars; and
a second lattice-shaped body including a plurality of second bars each having a bar shape extending in a second direction crossing the first direction and the arrangement direction within the first plane, and one ends of the plurality of second bars and the other ends of the plurality of second bars opposite to the one ends being spaced from each other in the arrangement direction, thereby forming a plurality of second trenches between the adjacent second bars,
wherein the first lattice-shaped body and the second lattice-shaped body are stacked in a stack direction perpendicular to the first plane.
